(19) United States
(12) Patent Application Publication
(10) Pub. No.: US 2025/0079248 A1
(43) Pub. Date: Mar. 6, 2025

(54) SEMICONDUCTOR PACKAGE AND METHOD OF MANUFACTURING SEMICONDUCTOR PACKAGE

(71) Applicant: Samsung Electronics Co., Ltd., Suwon-si (KR)

(72) Inventors: Myoungkyun Kil, Suwon-si (KR); Dahee Park, Suwon-si (KR)

(21) Appl. No.: 18/785,688

(22) Filed: Jul. 26, 2024

(30) Foreign Application Priority Data
Aug. 31, 2023 (KR) 10-2023-0115078

(51) Int. Cl. H01L 23/31; H01L 23/00

(52) U.S. Cl. CPC H01L 23/3128; H01L 24/16; H01L 24/96; H01L 24/97; H01L 2224/16227; H01L 2224/96; H01L 2224/97; H01L 2924/1815

(57) ABSTRACT

A semiconductor package includes a package substrate having a chip mounting region, a semiconductor chip on the chip mounting region of the package substrate and mounted on substrate pads of the package substrate via conductive bumps that are formed on chip pads of the semiconductor chip, a flow control member attached to an upper surface of the semiconductor chip, and a molding member on the semiconductor chip and the flow control member on the package substrate and in a gap between the package substrate and the semiconductor chip.

### CROSS-REFERENCE TO RELATED APPLICATION

This application claims priority under 35 U.S.C. § 119 to Korean Patent Application No. 10-2023-0115078, filed Aug. 31, 2023, in the Korean Intellectual Property Office (KIPO), the contents of which are herein incorporated by reference in their entirety.

### BACKGROUND

### 1. Field

Example embodiments relate to a semiconductor package and a method of manufacturing the semiconductor package. More particularly, example embodiments relate to a semiconductor package including a semiconductor chip stacked in a flip chip bonding manner and a method of manufacturing the same.

### 2. Description of the Related Art

In manufacturing a flip-chip package, a semiconductor chip is placed on a package substrate and then a molded underfill (MUF) process is performed to form a molding member. During the molded underfill process, a gap fill space of a molding material on an upper surface of the semiconductor chip is greater than a gap fill space between a lower surface of the semiconductor chip and an upper surface of the package substrate, thereby causing a difference in flow speed between molding materials flowing through upper and lower spaces of the semiconductor chip. Accordingly, voids may occur in the molding member below the semiconductor chip.

### SUMMARY

Example embodiments provide a semiconductor package configured to inhibit or prevent voids from occurring in a molding member and having improved reliability.

Example embodiments provide a method of manufacturing the semiconductor package.

According to example embodiments, a semiconductor package includes a package substrate having a chip mounting region, a semiconductor chip on the chip mounting region of the package substrate and mounted on substrate pads of the package substrate via conductive bumps that are formed on chip pads of the semiconductor chip, a flow control member attached to an upper surface of the semiconductor chip, and a molding member on the semiconductor chip and the flow control member on the package substrate and in a gap between the package substrate and the semiconductor chip.

According to example embodiments, a semiconductor package includes a package substrate having a chip mounting region, a semiconductor chip mounted on the chip mounting region of the package substrate such that a first surface on which conductive bumps are formed faces the package substrate, a flow control member attached to a second surface opposite to the first surface of the semiconductor chip, and a molding member on the semiconductor chip and the flow control member on the package substrate and in a gap between the package substrate and the semiconductor chip. A thickness of the flow control member is within a range of about 40 μm to about 100 μm.

According to example embodiments, a semiconductor package includes a package substrate having at least one molding material passage hole in a chip mounting region, a semiconductor chip mounted on the chip mounting region of the package substrate such that a first surface on which conductive bumps are formed faces the package substrate, a flow control member attached to a second surface opposite the first surface of the semiconductor chip, and a molding member on the semiconductor chip and the flow control member on the package substrate and in a gap between the package substrate and the semiconductor chip and the at least one molding material passage hole. A thickness of the flow control member is within a range of about 40 μm to about 100 μm. The flow control member includes a die attach film.

According to example embodiments, in a method of manufacturing a semiconductor package, conductive bumps are formed on a first surface of a semiconductor chip. A flow control member is attached to a second surface opposite to the first surface of the semiconductor chip. The semiconductor chip is mounted on a package substrate with the conductive bumps interposed therebetween. A molding apparatus is formed including a first mold having a seating surface on which the package substrate is seated and a second mold engageable with the first mold to form a molding space for molding the semiconductor chip. A molding material is supplied into the molding space to flow a first space between the semiconductor chip and the package substrate and a second space above the flow control member to thereby form a molding member that is on the semiconductor chip and the flow control member on the package substrate.

According to example embodiments, a semiconductor package may include a package substrate, a semiconductor chip mounted on the package substrate via conductive bumps, a flow control member attached to an upper surface of the semiconductor chip, and a molding member on the semiconductor chip and the flow control member on the package substrate and in a gap between the package substrate and the semiconductor chip.

The flow control member may be provided as a structure for controlling a flow of a molding material, such as EMC, within a mold in a transfer molding process to form the molding member. The flow control member may reduce a difference between a speed of the molding material passing through an upper space above the semiconductor chip within the cavity of the mold and a speed of the molding material passing through a lower space under the semiconductor chip. Accordingly, it may be possible to inhibit or prevent voids from occurring in the molding member between the package substrate and the semiconductor chip.

Additionally, the flow control member may include a material that is able to improve board level reliability. Thus, improved reliability at the board level may be obtained after the semiconductor package is mounted on the main board.

### BRIEF DESCRIPTION OF THE DRAWINGS

Example embodiments will be more clearly understood from the following detailed description taken in conjunction with the accompanying drawings. FIGS. 1 to 17 represent non-limiting, example embodiments as described herein.

FIG. 1 is a plan view illustrating a semiconductor package in accordance with example embodiments.

FIG. 2 is a cross-sectional view taken along the line A-A′ in FIG. 1.

FIGS. 3 to 13 are views illustrating a method of manufacturing a semiconductor package in accordance with example embodiments.

FIG. 14 is a plan view illustrating a semiconductor package according to example embodiments.

FIG. 15 is a cross-sectional view taken along the line D-D′ in FIG. 14.

FIG. 16 is a cross-sectional view illustrating a semiconductor package in accordance with example embodiments.

FIG. 17 is a cross-sectional view illustrating a semiconductor package in accordance with example embodiments.

### DETAILED DESCRIPTION OF EXAMPLE EMBODIMENTS

Hereinafter, example embodiments will be explained in detail with reference to the accompanying drawings. The same reference numerals are used for the same components in the drawings, and duplicate descriptions thereof are omitted. As used herein, the term “and/or” includes any and all combinations of one or more of the associated listed items. It is noted that aspects described with respect to one embodiment may be incorporated in different embodiments although not specifically described relative thereto. That is, all embodiments and/or features of any embodiments can be combined in any way and/or combination.

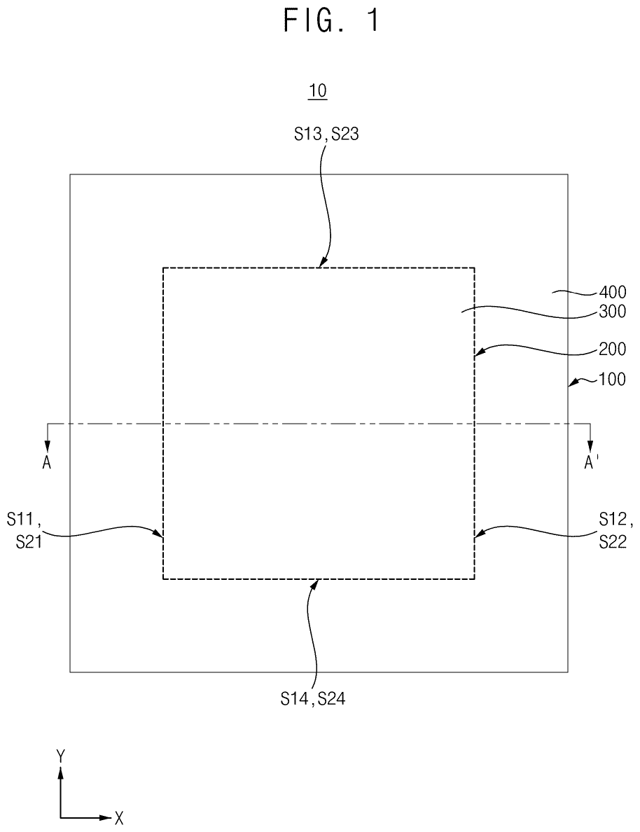

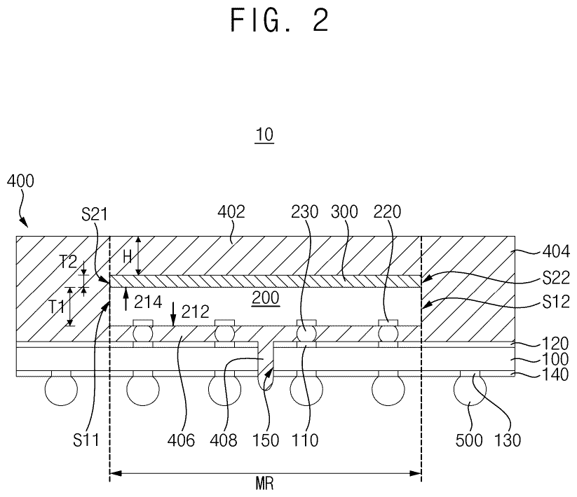

FIG. 1 is a plan view illustrating a semiconductor package in accordance with example embodiments. FIG. 2 is a cross-sectional view taken along the line A-A′ in FIG. 1.

Referring to FIGS. 1 and 2, a semiconductor package 10 may include a package substrate 100, a semiconductor chip 200 disposed on the package substrate 100, a flow control member 300 disposed on an upper surface of the semiconductor chip 200, and a molding member 400 that is on and at least partially covers the semiconductor chips 200 and the flow control member 300 on the package substrate 100. Additionally, the semiconductor package 10 may further include external connection members 500.

In example embodiments, the package substrate 100 may be a substrate having an upper surface and a lower surface opposite to each other. For example, the package substrate 100 may be a printed circuit board (PCB). The printed circuit board may be a multilayer circuit board having vias and various circuits therein.

The package substrate 100 may include a plurality of stacked insulating layers and wirings provided in the insulating layers. Additionally, the package substrate 100 may include a plurality of upper substrate pads 110 and a plurality of lower substrate pads 130. The wirings may include internal wirings that serve as channels for electrical connection with different types of semiconductor chips.

The upper substrate pads 110 may be exposed from the upper surface of the package substrate 100. A first upper insulating layer 120 may be provided on the insulating layers and may expose at least portions of the upper substrate pads 110. The lower substrate pads 130 may be at least partially exposed from the lower surface of the package substrate 100. A lower insulating layer 140 may be provided on the insulating layers and may expose at least portions of the lower substrate pads 130.

In example embodiments, the package substrate 100 may include a chip mounting region MR in a middle region thereof. The upper substrate pads 110 may be disposed within the chip mounting region MR of the package substrate 100. The upper substrate pads 110 may be arranged in an array in the chip mounting region MR. The package substrate 100 may have a rectangular shape with a first side (short side) and a second side (long side).

The package substrate 100 may include at least one molding material passage hole 150 within the chip mounting region MR. The molding material passage hole 150 may be formed to penetrate or extend into the package substrate 100. The molding material passage hole 150 may be formed by penetrating or extending into a portion of the insulating layer where internal circuit wirings are not formed. For example, a plurality of the molding material passage holes 150 may be arranged to be spaced apart from each other in one direction. The molding material passage holes 150 may be arranged along a center line passing through the center of the chip mounting region MR.

In example embodiments, the semiconductor chip 200 may be disposed on the chip mounting region MR. The semiconductor chip 200 may be mounted on the chip mounting region MR of the package substrate 100 via conductive bumps 230. The semiconductor chip 200 may be disposed, such that a front or first surface 212 on which chip pads 220 are formed, that is, an active surface, faces the package substrate 100. The chip pads 220 may be arranged in an array over the entire front surface of the semiconductor chip 200.

The semiconductor chip 200 may be mounted on the package substrate 100 using a flip chip bonding method. The chip pads 220 of the semiconductor chip 200 may be electrically connected to the upper substrate pads 110 of the package substrate 100 by the conductive bumps 230. A gap may be formed between the semiconductor chip 200 and the package substrate 100 by the conductive bumps 230.

For example, the conductive bump 230 may include a micro bump (uBump). Each of the conductive bumps 230 may include a conductive pillar as a lower bump and a solder as an upper bump. The conductive pillar may include a copper pillar (Cu pillar). The solder may include, for example, tin (Sn), tin/silver (Sn/Ag), tin/copper (Sn/Cu), tin/indium (Sn/In), tin/silver/copper (Sn/Ag/Cu), etc.

The conductive bump 230 under the semiconductor chip 200 may be electrically connected to the external connection member 500 by the upper substrate pad 110, the wirings in the package substrate 100, and the lower substrate pad 130. Accordingly, the semiconductor chip 200 may be electrically connected to an external device through the conductive bumps 230.

The semiconductor chip 200 may include a memory chip including a memory circuit. For example, the semiconductor chip may include volatile memory devices, such as SRAM devices, DRAM devices, etc. and non-volatile memory devices such as flash memory devices, PRAM devices, MRAM devices, RRAM devices, etc.

As illustrated in FIG. 1, the semiconductor chip 200 may have a rectangular shape with four sides when viewed in plan view. The semiconductor chip 200 may have a first chip side S11 and a second chip side S12 that extends in a direction orthogonal to the upper surface and parallel to the second direction (Y direction) and face each other, and a third chip side S13 and a fourth chip side S14 that extends in a direction parallel to the first direction (X direction) orthogonal to the second direction and face each other.

In example embodiments, the flow control member 300 may be attached to a backside surface, that is, the upper surface 214 of the semiconductor chip 200. The flow control member 300 may be on and at least partially cover the entire upper surface 214 of the semiconductor chip 200. The flow control member 300 may serve as a structure for controlling a flow of a molding material in a transfer molding process for forming the molding member 400.

The flow control member 300 may have a thermal expansion coefficient greater than that of the molding member 400 and an elastic coefficient greater than that of the molding member 400. The flow control member 300 may include an adhesive film, such as a die attach film. A thickness T2 of the flow control member 300 may be less than a thickness T1 of the semiconductor chip 200. The thickness T1 of the semiconductor chip 200 may be within a range of 50 μm to 250 μm, and the thickness T2 of the flow control member 300 may be within a range of 40 μm to 100 μm.

The thickness and material of the flow control member may be determined in consideration of flow rate conditions of the molding material in the transfer molding process for forming the molding member, board level reliability evaluation after the semiconductor package is mounted on the main board, etc.

As illustrated in FIG. 1, the flow control member 300 may have a rectangular shape with four sides when viewed in plan view. The flow control member 300 may have a first side S21 and a second side S22 that extend in a direction perpendicular to the upper surface and parallel to the second direction (Y direction) and facing each other, and a third side S23 and a fourth side S24 that extend in a direction parallel to the first direction (X direction) and face each other. The flow control member 300 may have the same planar area as the semiconductor chip 200. The first to fourth sides S21, S22, S23, and S24 of the flow control member 300 may overlap with the first to fourth chip sides S11, S12, S13, and S14 of the semiconductor chip 200, respectively.

In example embodiments, the molding member 400 may be on and at least partially cover the semiconductor chip 200 and the flow control member 300 on the package substrate 100. The molding member may include an epoxy mold compound (EMC).

The molding member 400 may include a first molding portion 402 that is on and at least partially covers the flow control member 300 on the semiconductor chip 200 and a second molding portion 404 that is on and at least partially covers the upper surface of the package substrate 100 around the semiconductor chip 200 and the flow control member 300. The first molding portion 402 of the molding member 400 may have a height H within a range of 150 μm to 250 μm from the upper surface of the flow control member 300.

In addition, the molding member 400 may include a third molding portion 406 that is in and at least partially fills a gap between the package substrate 100 and the semiconductor chip 200, and a fourth molding portion 408 that is in and at least partially fills the inside of the at least one molding material passage hole 150.

In example embodiments, lower substrate pads 130 may be formed on the lower surface of the package substrate 100 to provide electrical signals therethrough. The external connection member 500 may be disposed on the lower substrate pad 130 of the package substrate 100 for electrical connection with an external device. For example, the external connection member 500 may be a solder ball. The semiconductor package 10 may be mounted on a module substrate (not illustrated) using the solder balls to form a memory module.

As mentioned above, the semiconductor package 10 may include the package substrate 100, the semiconductor chip 200 mounted on the package substrate 100 via the conductive bumps 230, the flow control member 300 attached to the upper surface 214 of the semiconductor chip 200, and the molding member 400 on and at least partially covering the semiconductor chip 200 and the flow control member 300 on the package substrate 100 and at least partially filling the gap between the package substrate 100 and the semiconductor chip 200.

The flow control member 300 may be provided as a structure for controlling the flow of the molding material, such as EMC, within a mold in a transfer molding process to form the molding member 400. The flow control member 300 may reduce a difference between a speed of the molding material passing through an upper space above the semiconductor chip 200 within the cavity of the mold and a speed of the molding material passing through a lower space under the semiconductor chip. Accordingly, it may be possible to inhibit or prevent voids from occurring in the molding member 400 between the package substrate 100 and the semiconductor chip 200.

Additionally, the flow control member 300 may include a material that is able to improve board level reliability. Thus, improved reliability at the board level may be obtained after the semiconductor package 10 is mounted on the main board.

Hereinafter, a method of manufacturing the semiconductor package in FIG. 1 will be explained.

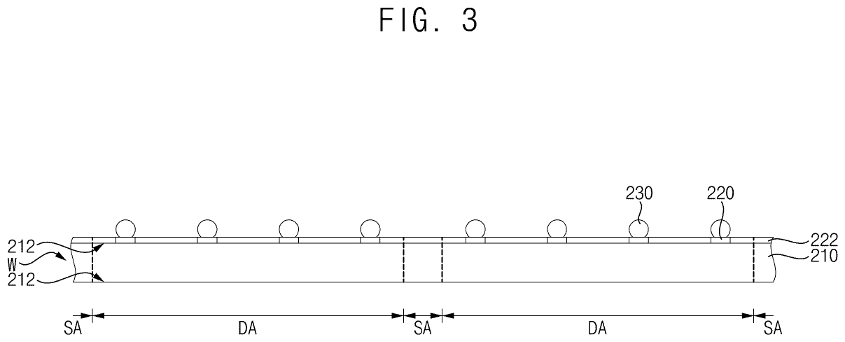

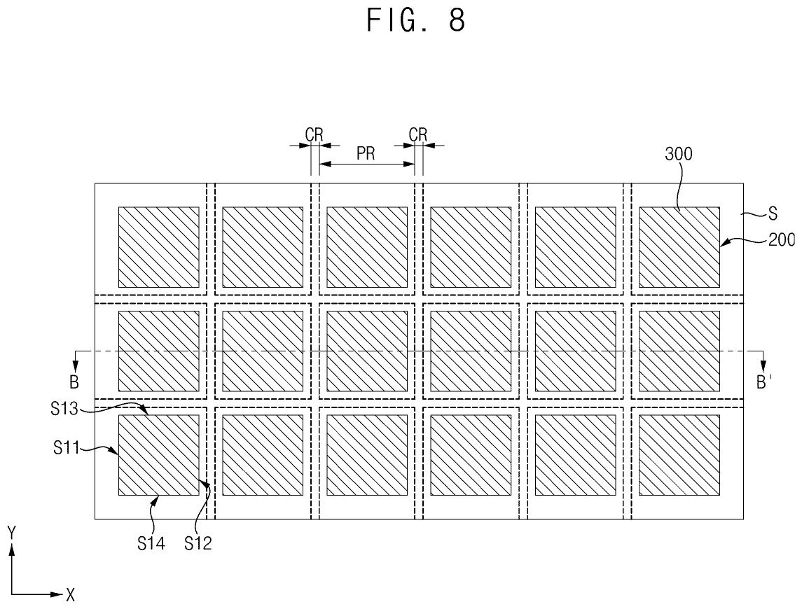

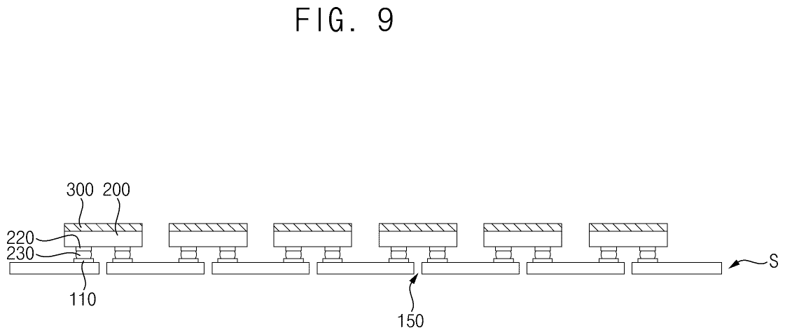

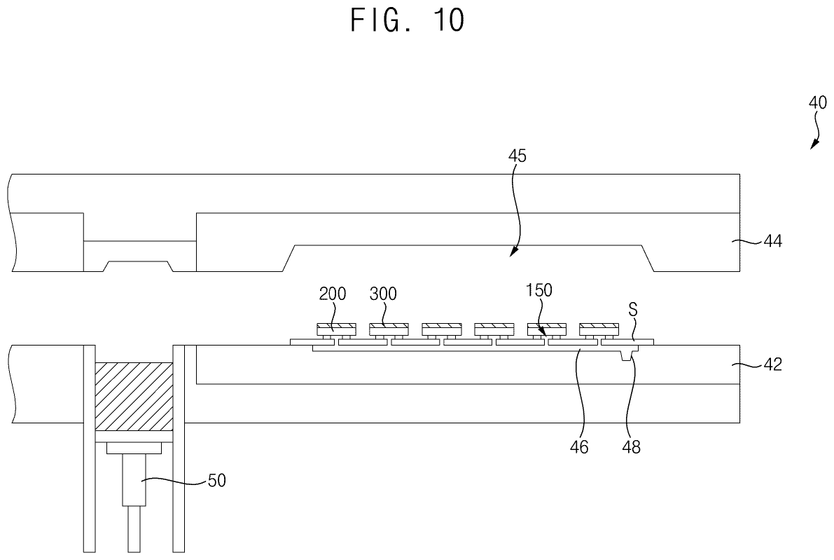

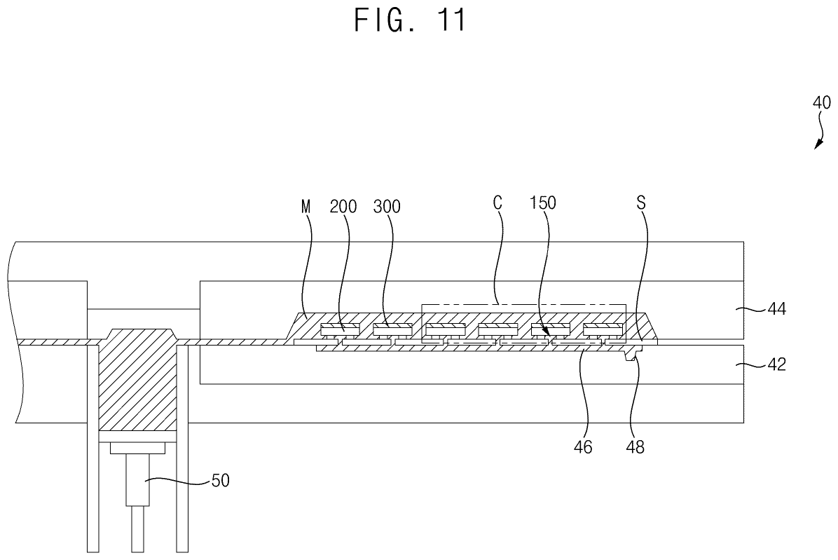

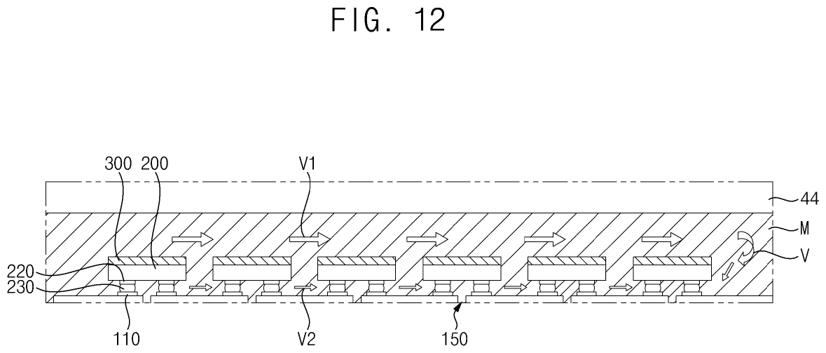

FIGS. 3 to 13 are views illustrating a method of manufacturing a semiconductor package in accordance with example embodiments. FIGS. 3 to 7 are views illustrating a process of forming a semiconductor chip on which conductive bumps are disposed. FIGS. 8 and 9 are views illustrating semiconductor chips mounted on a package substrate. FIG. 9 is a cross-sectional view taken along the line B-B′ in FIG. 8. FIGS. 10 to 12 are views illustrating a process of forming a molding member on a package substrate using a molding apparatus. FIG. 12 is an enlarged cross-sectional view illustrating portion ‘C’ in FIG. 11.

Referring to FIGS. 3 to 7, conductive connection members 230 may be formed on chip pads 210 of a semiconductor chip 200.

As illustrated in FIG. 3, first, a wafer W on which a plurality of semiconductor chips (die) is formed may be prepared, and then, the conductive connection members 230 may be formed on the chip pads 210 of the semiconductor chip 200.

In example embodiments, the wafer W may include a substrate 210 having a first or front surface 212 and a second or upper surface 214 opposite to the first surface 212. Additionally, the wafer W may include a front insulating layer (not illustrated) formed on the first surface 212 of the substrate 210.

The substrate 210 may include a die region DA where circuit patterns and cells are formed and a scribe lane region SA surrounding the die region DA in a plan view. As described below, the substrate 210 may be cut along the scribe lane region SA that divides the plurality of die regions DA of the wafer W by a following dicing process to be individualized.

The circuit patterns may include transistors, capacitors, diodes, etc. The circuit patterns may constitute circuit elements. Accordingly, the semiconductor chip may be a semiconductor device in which a plurality of the circuit elements is formed. The circuit patterns may be formed on the first surface 212 of the substrate 210, that is, an active surface, by performing a FEOL (Front End of Line) process for manufacturing semiconductor devices. The surface of the substrate on which the FEOL process is performed may be referred to as a front surface of the substrate, and the surface opposite to the front surface may be referred to as a backside surface.

The front insulation layer as an insulation interlayer may be provided on the first surface 212 of the substrate 210 to be on and at least partially cover the circuit patterns. The front insulation layer may include a plurality of insulation layers and upper wirings in the insulation layers. A chip pad 230 may be provided in the outermost insulation layer of the front insulation layer. The chip pad 230 may be electrically connected to the circuit element by the upper wirings. As will be described below, at least a portion of the chip pad 230 may serve as a landing pad on which a connection member, such as a signal transmission bump is disposed.

The semiconductor chips may be memory chips. For example, the semiconductor chip may include volatile memory devices, such as SRAM devices, DRAM devices, etc. and non-volatile memory devices, such as flash memory devices, PRAM devices, MRAM devices, RRAM devices, etc.

Then, an insulating layer may be formed on the chip pad 220, and portions of the insulating layer may be removed to expose a portion of the chip pad 220 to form an insulating layer pattern 222. Then, a conductive bump 230 as the conductive connection member may be formed on the portion of the chip pad 220 exposed by the insulating layer pattern. The conductive bump 230 may be electrically connected to the circuit pattern by the chip pad and the upper wiring to serve as the signal transmission bump. For example, the insulating layer may include photosensitive polyimide (PSPI). Although not illustrated in the figures, a protective layer pattern at least partially exposing the chip pad 220 may be formed under the insulating layer pattern. For example, the conductive bumps may be formed by a plating process. In other embodiments, the conductive bumps may be formed by a screen printing process, a deposition process, etc.

For example, each of the conductive bumps 230 may include a conductive pillar as a lower bump and a solder as an upper bump. The conductive pillar may include a copper pillar (Cu pillar). The solder may include, for example, tin (Sn), tin/silver (Sn/Ag), tin/copper (Sn/Cu), tin/indium (Sn/In), and/or tin/silver/copper (Sn/Ag/Cu), etc.

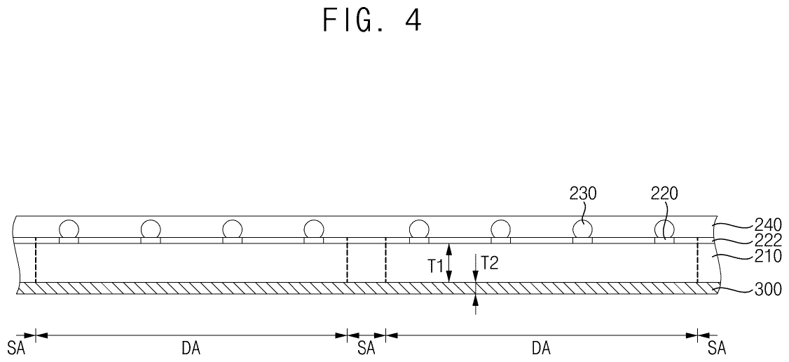

As illustrated in FIG. 4, a flow control member 300 may be attached to the second surface 214 of the substrate 210.

In example embodiments, after the second surface 214 of the substrate 210 may be polished, such that the wafer W has a desired thickness, the flow control member 300 may be attached to the entire second surface 214 of the substrate 210.

After a protective tape 240 is attached on the first surface 212 of the wafer W to protect the circuit elements and the conductive bumps 230, the second side 214 of the wafer W may be partially removed by a grinding process such that the wafer has a desired thickness. The wafer may be polished to have a thickness of, for example, 50 μm to 250 μm.

After performing the grinding process, the flow control member 300 may be attached to the second side 214 of the wafer W. After performing the grinding process, the protective tape 240 may be removed from the wafer W.

The flow control member 300 may be provided as a structure for controlling a flow of a molding material such as EMC within a mold in a subsequent transfer molding process. The flow control member 300 may reduce a difference between a speed of the molding material passing through an upper space over the semiconductor chip and a speed of the molding material passing through a lower space under the semiconductor chip within a cavity of the mold. For example, a thickness of the flow control member 300 may be within a range of 40 μm to 100 μm.

Additionally, the flow control member 300 may include a material that is able to improve board level reliability. For example, the flow control member 300 may have a thermal expansion coefficient greater than that of the molding material and an elastic coefficient greater than that of the molding material. For example, the flow control member 300 may include a die attach film (DAF).

Then, the wafer W may be cut by a dicing process to form individual semiconductor chips 200.

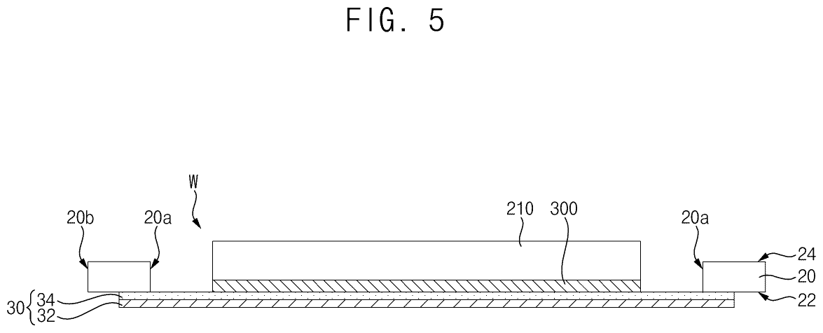

As illustrated in FIG. 5, a dicing tape 30 may be attached to a lower surface 22 of a ring frame 20, and the flow control member 300 that is attached to the semiconductor wafer W in which the plurality of semiconductor chips are formed may be attached to the dicing tape 30. The dicing tape 30 may include a base film 32 and an adhesive layer 34 provided on the base film 32.

In example embodiments, the dicing tape 30 may be attached to the ring frame 20 by an adhesive force of the adhesive layer 34. The ring frame 20 may have an inner surface 20a that defines a receiving space inside and an outer surface 20b that is radially opposite to the inner surface 20a. The flow control member 300 on the adhesive layer 34 of the dicing tape 30 may be disposed within the receiving space of the ring frame 20. The flow control member 300 may be spaced apart from the inner surface 20a of the ring frame 20.

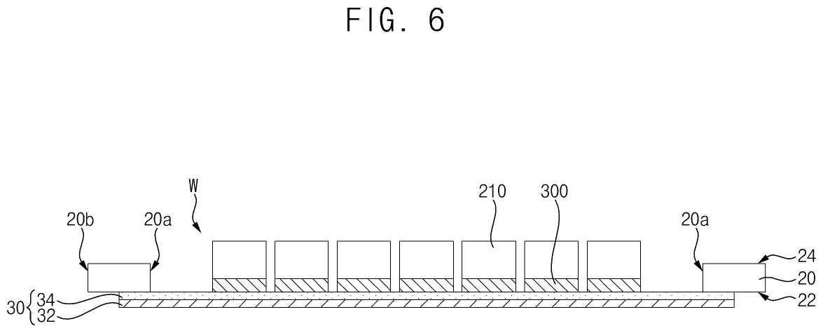

As illustrated in FIG. 6, the dicing process may be performed to form a cutting line for dividing the wafer W into a plurality of semiconductor chips. For example, the dicing process may be performed by irradiating a laser beam along the scribe lane region or using a blade.

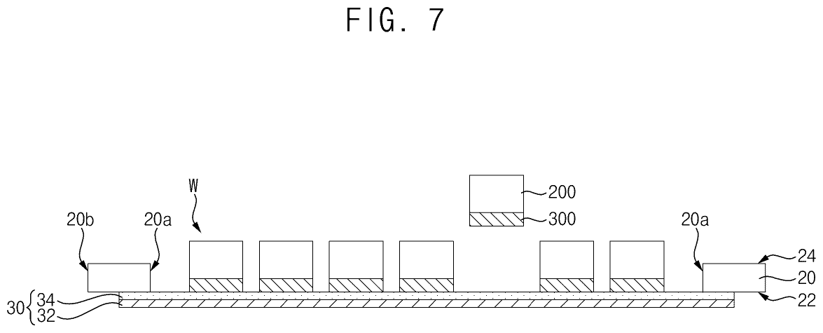

As illustrated in FIG. 7, the dicing tape 30 may be expanded to separate the wafer W into the plurality of semiconductor chips 200. By expanding the dicing tape in the radial direction using a tape expansion apparatus, the divided semiconductor chips 200 on the dicing tape may be spaced apart from each other in the radial direction.

The diced semiconductor chip 200 may have a rectangular shape with four sides when viewed in plan view. The diced flow control member 300 may also have the same shape as the semiconductor chip 200 when viewed in plan view. The flow control member 300 may be on and at least partially cover the entire backside surface of the semiconductor chip 200.

As will be described below, the semiconductor chip 200 to which the flow control member 300 is attached may be attached to a package substrate or another semiconductor chip through a pickup process to form a semiconductor package.

Referring to FIGS. 8 and 9, the semiconductor chip 200 may be mounted on the package substrate with the conductive bumps 230 interposed therebetween.

In example embodiments, a strip substrate S including a plurality of package substrates for mounting the individualized semiconductor chips 200 may be prepared. The strip substrate S may be a multilayer circuit board as a package substrate having an upper surface and a lower surface opposite to each other. For example, the strip board may be a printed circuit board (PCB) including wirings respectively provided in a plurality of layers and vias connected to the wirings.

As illustrated in FIG. 8, the strip substrate S may include a package region PR on which the semiconductor chips 200 are respectively mounted and a cutting region CR surrounding the package region PR in a plan view. The strip substrate S may be individualized into a semiconductor package by cutting the cutting region CR through a subsequent sawing process. For example, 50 to 300 semiconductor chips 200 may be mounted on one strip board S.

As illustrated in FIG. 9, the semiconductor chip 200 may be mounted on a chip mounting region of the package region PR of the strip substrate S using a flip chip bonding method. The strip board S may have at least one molding material passage hole 150 in the chip mounting region.

For example, flux may be applied on surfaces of the conductive bumps 230 on the semiconductor chip 200, and the semiconductor chips 200 may be respectively disposed within the package regions PR of the strip substrate S. The conductive bumps 230 may be interposed between the strip substrate S and the semiconductor chip 200. The conductive bump 230 may be disposed on an upper substrate pad 110 of the strip substrate. Then, the conductive bump 230 may be bonded to the upper substrate pad 110 by a reflow process.

Referring to FIGS. 10 to 13, a molding member 400 may be formed on the strip substrate S to be on and at least partially cover the semiconductor chips 200.

As illustrated in FIGS. 10 and 11, a molded underfill (MUF) process may be performed using a molding apparatus 40. The molding apparatus 40 may include a mold having a lower mold 42 and an upper mold 44 that are clamped to each other to form a molding space for molding the semiconductor chips 200. The molding apparatus 40 may be a transfer molding apparatus that transfers a liquid molding material M into the molding space to mold the semiconductor chip.

The semiconductor chip may be placed in the molding space, and the molding material may flow under high temperature and pressure while the lower mold 42 and the upper mold 44 are clamped, so that the liquid molding material M flows inside the molding space and then solidifies to form the molding member 400 that is on and at least partially covers the semiconductor chip. For example, the molding material may include epoxy mold compound (EMC).

The molding material M in a tablet state from a molding material supply may be provided onto a plunger 50 and may be heated to have fluidity. Then, as the plunger 50 rises, the liquid molding material M may flow into the molding space by the pressure of the plunger 50 and then solidifies to form the molding member 400 on the strip substrate S.

As illustrated in FIG. 12, because the upper and lower spaces above and under the semiconductor chip 200 within the cavity 45 are different, a difference in flow speed between the molding material M flowing through the upper and lower spaces may occur. The molding material M injected into the cavity 45 may move through the upper space above the semiconductor chip 200 at a first speed V1 and may move through the lower space between the semiconductor chip 200 and the strip substrate S at a second speed V2 less than the first speed V1. Because the flow speed of the molding material M flowing in the space between the semiconductor chip 200 and the strip substrate S is relatively slow, voids may be generated in the mold.

The flow control member 300 may be attached to the upper surface of the semiconductor chip 200 to reduce a height (gap) between the upper surface of the semiconductor chip 200 and a lower surface of the upper mold 44, to thereby reduce the difference in flow speed between the flowing molding materials M through the upper space and the lower space.

The mold may be provided with a vent for exhausting gas in the molding space as the molding material M is introduced into the cavity. A vortex V of the molding material M may be generated at one end portion of the molding space adjacent to the vent. The flow control member 300 may control the flow rate at one end portion of the molding space to inhibit or prevent the generation of the vortex.

When the molding material M is injected into the cavity 45 during the molded underfill (MUF) process, the air inside the cavity 45 may be exhausted to the outside through the molding material passage hole 150 to improve resin filling rate. The molding material M may fill the interior of the molding material passage hole 150 and then may be collected into a molding material reservoir 48 through a molding material flow channel 46 of the lower mold 42.

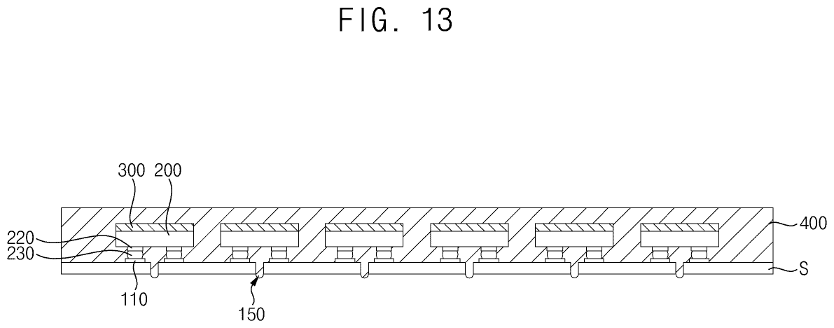

Then, after curing the molding material for a certain period of time, external connection members such as solder balls may be formed on lower substrate pads on the lower surface of the strip substrate S of FIG. 13, and the strip substrate S may be individually separated along the cutting region CR by a sawing process, to complete the flip chip semiconductor package 10 of FIG. 1.

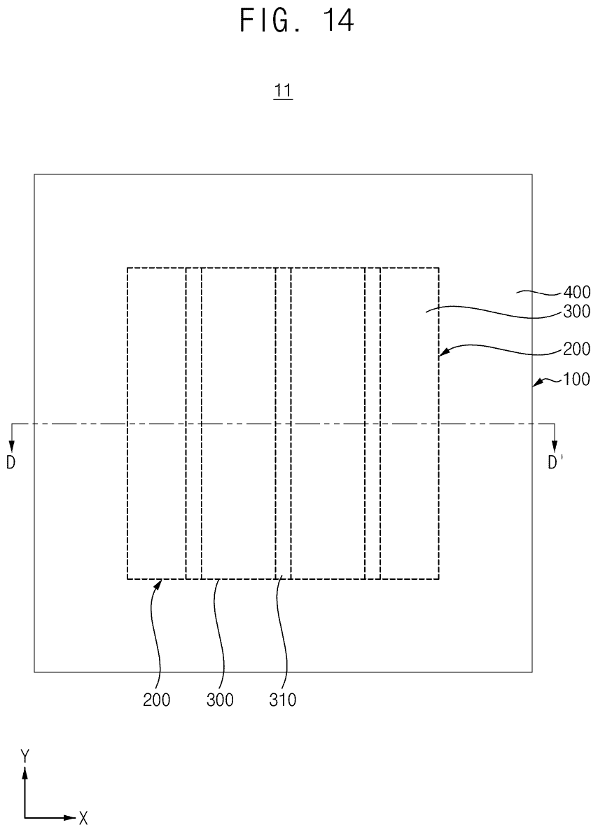

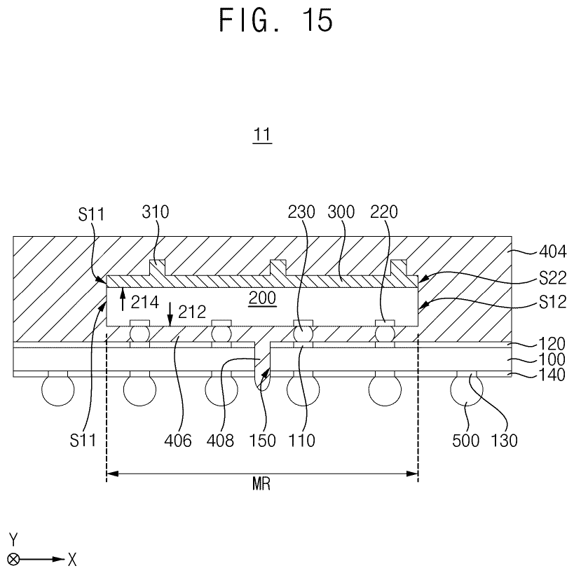

FIG. 14 is a plan view illustrating a semiconductor package according to example embodiments. FIG. 15 is a cross-sectional view taken along the line D-D′ in FIG. 14. The semiconductor package may be substantially the same as the semiconductor package described with reference to FIGS. 1 and 2 except for a configuration of a flow control member. Thus, the same reference numerals may be used to refer to the same or like elements and any further repetitive explanation concerning the above elements will be omitted.

Referring to FIGS. 14 and 15, a flow control member 300 of a semiconductor package 11 may include at least one flow control pattern that extends in one direction, e.g., the Y direction. The at least one flow control pattern may include at least one protruding pattern 310 provided on an upper surface of the flow control member 300.

A plurality of the protruding patterns 310 may be arranged to be spaced apart from each other along a first direction (X direction). Each of the protruding patterns 310 may extend in a second direction (Y direction). The protruding pattern 310 may have a predetermined height from the upper surface of the flow control member 300 and a predetermined width in the first direction.

The protruding patterns 310 on the upper surface of the flow control member 300 may be arranged to extend in a direction perpendicular to a flow direction of a molding material such as EMC in a mold of a transfer molding apparatus, to control a speed of the molding material passing through an upper space above the flow control member 300.

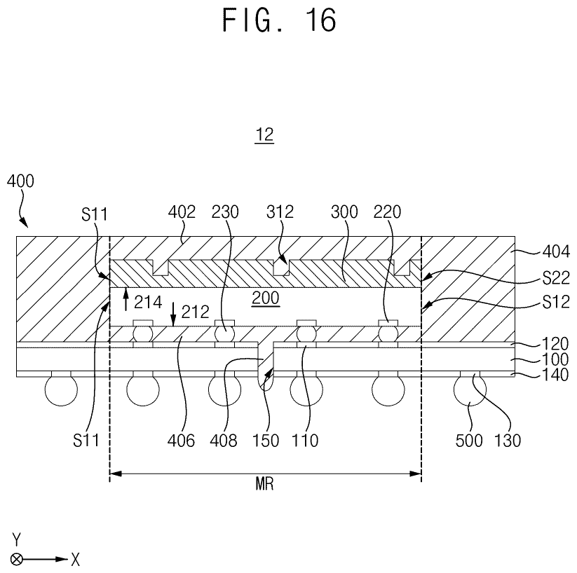

FIG. 16 is a cross-sectional view illustrating a semiconductor package in accordance with example embodiments. FIG. 16 is a cross-sectional view taken along the line D-D′ in FIG. 14. The semiconductor package may be substantially the same as the semiconductor package described with reference to FIGS. 14 and 15 except for a configuration of a flow control member. Thus, the same reference numerals may be used to refer to the same or like elements and any further repetitive explanation concerning the above elements will be omitted.

Referring to FIG. 16, a flow control member 300 of a semiconductor package 12 may include at least one flow control pattern that extends in one direction, e.g., the Y direction. The at least one flow control pattern may include at least one groove pattern 312 provided in an upper surface of the flow control member 300.

A plurality of the groove patterns 312 may be arranged to be spaced apart from each other along a first direction (X direction). Each of the groove patterns 312 may extend in a second direction (Y direction). The groove pattern 312 may have a predetermined depth from the upper surface of the flow control member 300 and a predetermined width.

The groove patterns 312 in the upper surface of the flow control member 300 may be arranged to extend in a direction perpendicular to a flow direction of a molding material, such as EMC in a mold of a transfer molding apparatus to control a speed of the molding material passing through an upper space above the flow control member 300.

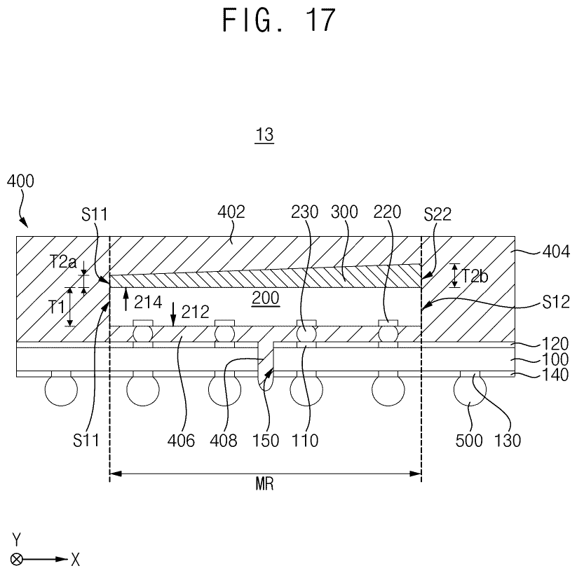

FIG. 17 is a cross-sectional view illustrating a semiconductor package in accordance with example embodiments. FIG. 17 is a cross-sectional view taken along the line A-A′ in FIG. 1. The semiconductor package may be substantially the same as the semiconductor package described with reference to FIGS. 1 and 2 except for a configuration of the flow control member. Thus, the same reference numerals may be used to refer to the same or like elements and any further repetitive explanation concerning the above elements will be omitted.

Referring to FIG. 17, a flow control member 300 of a semiconductor package 13 may have a first side S21 and a second side S22 that extend in a direction (Y direction) parallel to each other and face each other. A thickness of the flow control member 300 may gradually increase in a first direction (X direction). A thickness T2a of the first side S21 may be less than a thickness T2b of the second side S22.

The first side S21 and the second side S22 of the flow control member 300 may be arranged to extend in a direction perpendicular to a flow direction of a molding material, such as EMC in a mold of a transfer molding apparatus. The thickness of the flow control member 300 may gradually increase along a flow direction of the molding material to control a speed of the molding material passing through an upper space above the flow control member 300.

The semiconductor package may include semiconductor devices, such as logic devices or memory devices. The semiconductor package may include logic devices such as central processing units (CPUs), main processing units (MPUs), or application processors (APs), or the like, and volatile memory devices such as DRAM devices, HBM devices, or non-volatile memory devices, such as flash memory devices, PRAM devices, MRAM devices, ReRAM devices, or the like.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of example embodiments as defined in the claims.

What is claimed is:

1. A semiconductor package, comprising:
a package substrate having a chip mounting region;
a semiconductor chip on the chip mounting region of the package substrate and mounted on substrate pads of the package substrate via conductive bumps that are formed on chip pads of the semiconductor chip;
a flow control member attached to an upper surface of the semiconductor chip; and
a molding member on the semiconductor chip and the flow control member on the package substrate and in a gap between the package substrate and the semiconductor chip.

2. The semiconductor package of claim 1, wherein the flow control member has a coefficient of thermal expansion greater than a coefficient of thermal expansion of the molding member and an elastic coefficient greater than an elastic coefficient of the molding member.

3. The semiconductor package of claim 1, wherein the flow control member includes a die attach film.

4. The semiconductor package of claim 1, wherein a thickness of the flow control member is within a range of about 40 μm to about 100 μm.

5. The semiconductor package of claim 1, wherein a height of the molding member from the upper surface of the flow control member is within a range of about 150 μm to about 250 μm.

6. The semiconductor package of claim 1, wherein, when viewed in plan view, the semiconductor chip and the flow control member have a same shape.

7. The semiconductor package of claim 1, wherein the flow control member includes at least one protruding pattern in an upper surface and that has a predetermined height from the upper surface of the flow control member and a width and extends in one direction;
wherein a direction of the predetermined height, a direction of the width, and the one direction are each perpendicular with respect to each other.

8. The semiconductor package of claim 1, wherein the flow control member includes at least one groove pattern in an upper surface and that has a predetermined depth from the upper surface of the flow control member and a width and extends in one direction;
wherein a direction of the predetermined depth, a direction of the width, and the one direction are each perpendicular with respect to each other.

9. The semiconductor package of claim 1, wherein the flow control member has a first side and a second side that extend in a first direction and face each other, and a thickness of the flow control member increases in a second direction perpendicular to the first direction.

10. The semiconductor package of claim 1, wherein the package substrate has at least one molding material passage hole within the chip mounting region, and a portion of the molding member is in the at least one molding material passage hole.

11. A semiconductor package, comprising:
a package substrate having a chip mounting region;
a semiconductor chip mounted on the chip mounting region of the package substrate, such that a first surface on which conductive bumps are formed faces the package substrate;
a flow control member attached to a second surface opposite to the first surface of the semiconductor chip; and
a molding member on the semiconductor chip and the flow control member on the package substrate and in a gap between the package substrate and the semiconductor chip,
wherein a thickness of the flow control member is within a range of about 40 μm to about 100 μm.

12. The semiconductor package of claim 11, wherein the flow control member includes a die attach film.

13. The semiconductor package of claim 11, wherein the flow control member has a coefficient of thermal expansion greater than a coefficient of thermal expansion of the molding member and an elastic coefficient greater than an elastic coefficient of the molding member.

14. The semiconductor package of claim 11, wherein the flow control member is on the entire second surface of the semiconductor chip.

15. The semiconductor package of claim 11, wherein, when viewed in plan view, the semiconductor chip and the flow control member have a same shape.

16. The semiconductor package of claim 11, wherein the flow control member includes at least one flow control pattern in an upper surface of the flow control member and that extends in one direction.

17. The semiconductor package of claim 16, wherein the at least one flow control pattern includes a protruding pattern that has a predetermined height from the upper surface of the flow control member and a predetermined width.

18. The semiconductor package of claim 16, wherein the at least one flow control pattern includes a groove pattern that has a predetermined depth from an upper surface of the flow control member and that has a predetermined width;
wherein a direction of the predetermined depth, a direction of the predetermined width, and the one direction are each perpendicular with respect to each other.

19. The semiconductor package of claim 11, wherein the flow control member has a first side and a second side that extend in a first direction and face each other, and a thickness of the first side is less than a thickness of the second side.

20. A semiconductor package, comprising:
a package substrate having at least one molding material passage hole in a chip mounting region;
a semiconductor chip mounted on the chip mounting region of the package substrate, such that a first surface on which conductive bumps are formed faces the package substrate;
a flow control member attached to a second surface opposite the first surface of the semiconductor chip; and
a molding member on the semiconductor chip and the flow control member on the package substrate and in a gap between the package substrate and the semiconductor chip and the at least one molding material passage hole,
wherein a thickness of the flow control member is within a range of about 40 μm to about 100 μm, and the flow control member includes a die attach film.
